(19) United States
(12) Patent Application Publication
(10) Pub. No.: US 2007/0216003 A1
(43) Pub. Date: Sep. 20, 2007

(54) Semiconductor package with enhancing layer and method for manufacturing the same

(75) Inventors: Hui-Pin Chen, Kaohsiung (TW); Chia-Chieh Hu, Kaohsiung (TW)

Correspondence Address: BIRCH STEWART KOLASCH & BIRCH, PO BOX 747, FALLS CHURCH, VA, 22040-0747, US

(73) Assignee: Advanced Semiconductor Engineering. Inc.

(21) Appl. No.: 11/656,427

(22) Filed: Jan. 23, 2007

(30) Foreign Application Priority Data
Mar. 15, 2006 (TW) 95108840

(51) Int. Cl. H01L 23/02

(52) U.S. Cl. 257/678

(57) ABSTRACT

A semiconductor package with an enhancing layer is provided. The package includes a leadframe, a chip, several bumps and an enhancing layer. The leadframe includes several leads. Several bonding pads are disposed on a surface of the chip. The bumps connect the bonding pads of the chip and the leads of the leadframe. The enhancing layer covers the leads and the bumps. The enhancing layer including copper is formed by electroplating. Or, the melting point of the enhancing layer is greater than the melting points of lead and tin.

This application claims the benefit of Taiwan application Serial No. 95108840, filed Mar. 15, 2006, the subject matter of which is incorporated herein by reference.

### BACKGROUND OF THE INVENTION

1. Field of the Invention

The invention relates in general to a semiconductor package and a method for manufacturing the same, and more particularly to a semiconductor package with an enhancing layer and a method for manufacturing the same.

2. Description of the Related Art

Recently, portable terminal products, such as notebooks, mobile phones, personal digital assistants and digital camera, have become a main trend in the market. Considerable efforts have been made to minimize the volume and weight of portable terminal products. Take mobile phones for example. Under the demand for minimizing the volume and weight, chips are developed in coordination with electronic devices to be digital, high processing speed, multi-functional and miniaturized.

According to the above demands, chip packages have to be miniaturized and have good heat dissipating ability. Therefore, RF IC chips are evolved from SOP packages into QFN packages. In order to have higher frequency and less volume, more and more companies are investigating the possibilities of FCQFN packages. As a result, FCQFN have become one of the hottest packages. However, there are still some unsolved problems in FCQFN packages. For example, eutectic solder bumps collapse after reflowing. Furthermore, because the reflowing temperature of lead-free and high-lead bumps is too high, difference of thermal expansion coefficient between the chip and the leadframe is so large that the bumps collapse after packaging. Therefore, the chips are affected by moisture and heat and not electrically connected to an outer circuit effectively. The chips are not sufficiently protected through the packaging process.

The best solution of the problems in FCQFN packages is adhering gold stud bumps to high conductive silver paste baked at low temperature. Accordingly, FCQFN packages have problems including bump collapse and huge difference of thermal expansion coefficient between the chip and the frame. After a reliability experiment, collapse occurs between the frame and the conductive silver paste because the silver paste can not bear strong stress. Therefore, it is very important to strengthen the structure of packages.

Please referring to FIG. 1, a conventional semiconductor package is illustrated in FIG. 1. A conventional semiconductor package includes a leadframe 20, a chip 10, several bumps 13 and an encapsulant material 30. The leadframe 20 includes several leads 21. Several bonding pads 11 are disposed on a surface of the chip 10. The bumps 13 connect the bonding pads 11 of the chip 10 and the leads 21 of the leadframe 20. The bumps 13 further include several adhesives. The encapsulant material 30 covers the bumps 13 and a portion of the leadframe 20.

FIG. 2 is a flow chart of a conventional method for manufacturing a semiconductor package. Please referring to FIG. 2, the conventional method for manufacturing a semiconductor package includes following steps. First, in a step S100, a leadframe 20 including several leads 21 is provided. Next, in a step S110, a chip 10 is provided. Several bonding pads 11 are disposed on a surface of the chip 10. Then, in a step S120, several bumps 13 are formed on the bonding pads 11. The bumps 13 further include several adhesives. Afterwards, in a step S130 the bumps 13 of the chip 10 are disposed on the leads 21 of the leadframe 20. Subsequently, in a step S140, the adhesives are solidified. Thereon, in a step S150, an encapsulant material 30 is filled to cover a portion of the chip 10, the bumps 13 and a portion of the leadframe 20.

However, there are still some unsolved problems due to material properties in the above method for manufacturing a semiconductor package. For example, eutectic solder bumps collapse after reflowing. Also, because the reflowing temperature of lead-free and high-lead bumps is too high, the difference of thermal expansion coefficient between the chip and the frame is so large that the bumps collapse after packaging. Therefore, the chips are affected by moisture and heat and not electrically connected to an outer circuit effectively. The chips are not sufficiently protected through the packaging process. Hence, there are still a lot of problems to be solved in the conventional packaging technology.

### SUMMARY OF THE INVENTION

The invention is directed to a semiconductor package with an enhancing layer and a method for manufacturing the same to satisfy the above demands.

According to the present invention, a semiconductor package with an enhancing layer and a method for manufacturing the same are provided. The semiconductor package includes an enhancing layer preferably covering bumps and leads of a leadframe. Or, the enhancing layer covers only conductive adhesives of the bumps. The enhancing preferably includes copper. Or, the melting point of the enhancing layer is greater than the melting points of lead and tin. The enhancing layer is formed by electroplating.

Therefore, in a FCQFN package of the present invention, copper or another metal with thickness about 10-30 μm is easily electroplated on the bumps and in other regions of the package because the space around the bumps after flip-chip step is large enough. The advantages are as follow. First, the mechanical strength of the bumps is enhanced. The method can also be applied to general eutectic solder bumps. Second, the bumps are prevented from collapsing at high temperature. The melting point of copper is high, so that most of the currency flows through the surfaces of the bumps when high frequent signals are transmitted. As a result, the conductivity is increased greatly. Third, the problem of high resistance in flip chip packages with gold stud bumps adhered to silver paste is solved. Therefore, the packages of the present invention are suitable for products with high frequency.

The conventional packaging problems due to the material properties are solved. Chips are prevented from moisture and heat. Besides, chips are electrically connected to an outer circuit effectively to achieve the goal of chip packaging.

The invention will become apparent from the following detailed description of the preferred but non-limiting embodiments. The following description is made with reference to the accompanying drawings.

### BRIEF DESCRIPTION OF THE DRAWINGS

FIG. 1 (Prior Art) illustrates a conventional semiconductor package;

FIG. 2 (Prior Art) is a flow chart of a conventional method for manufacturing a semiconductor package;

FIGS. 3A˜3F illustrate semiconductor packages with enhancing layers according to preferred embodiments of the invention;

FIG. 4 is a flow chart of a method for manufacturing a semiconductor package with an enhancing package according to a preferred embodiment of the invention; and

FIGS. 5A˜5F illustrate the method for manufacturing a semiconductor package with an enhancing package according to a preferred embodiment of the invention.

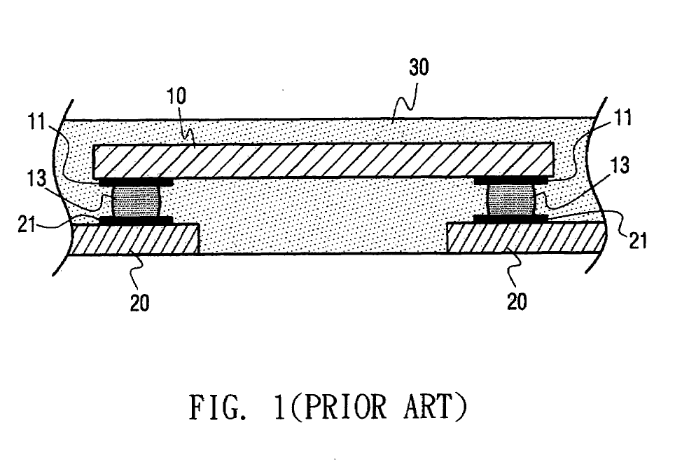

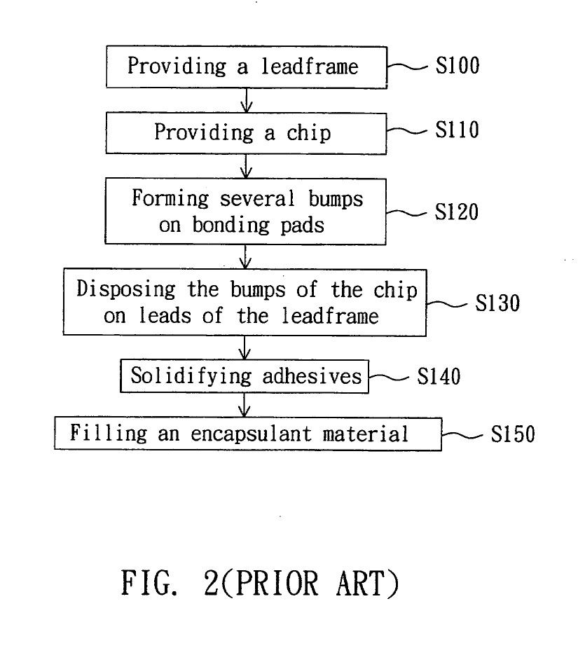

### DETAILED DESCRIPTION OF THE INVENTION

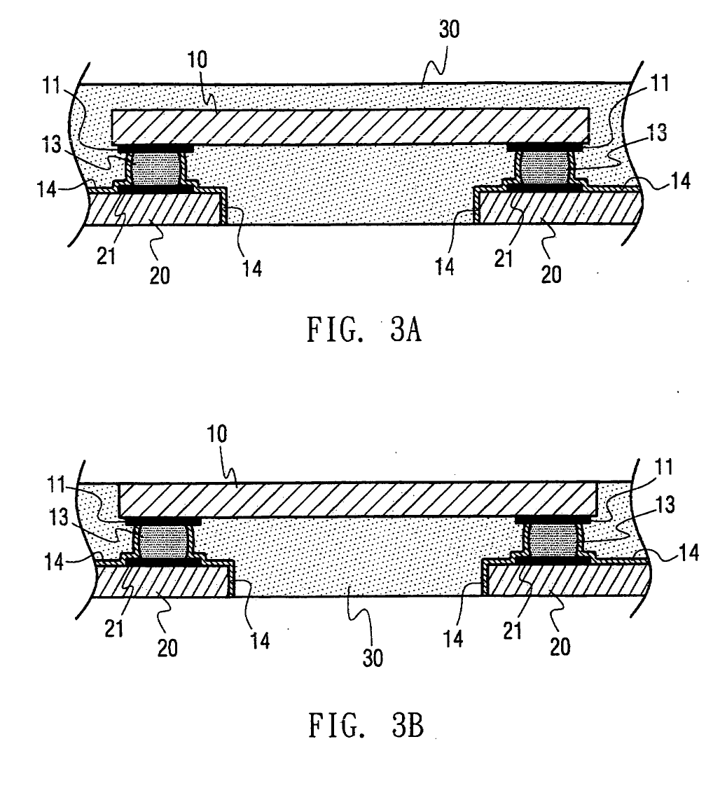

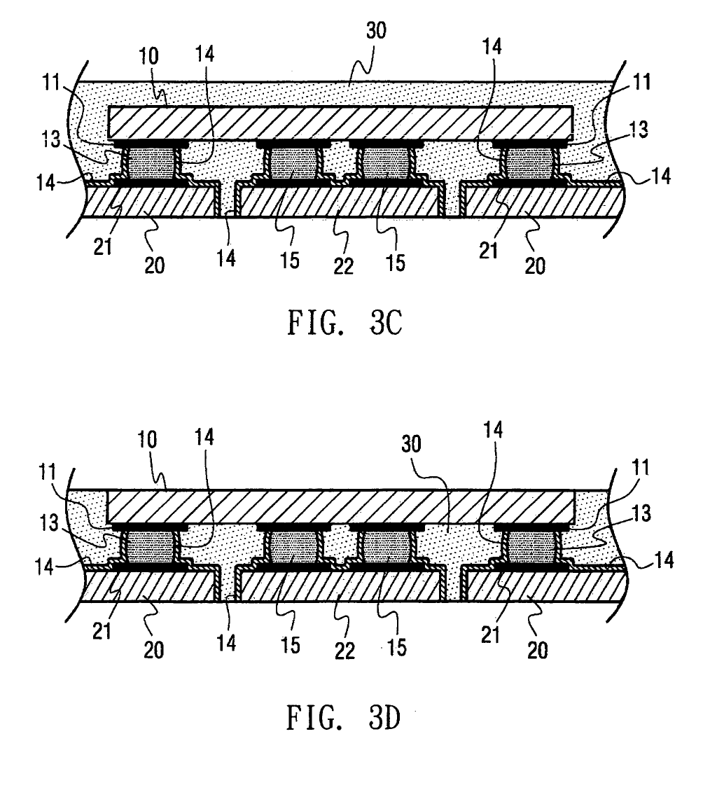

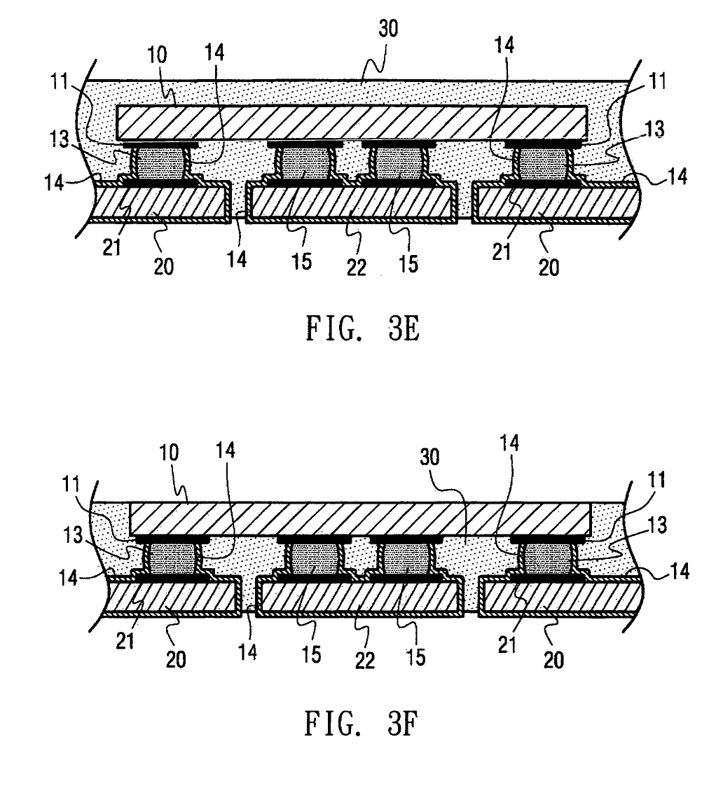

Please referring to FIG. 3A, a semiconductor package with an enhancing layer according to a preferred embodiment of the invention is illustrated in FIG. 3A. The semiconductor package includes a leadframe 20, a chip 10 several bumps 13, an enhancing layer 14 and an encapsulant material 30. The leadframe 20 includes several leads 21. Several bonding pads 11 are disposed on a surface of the chip 10. The bumps 13 connect the bonding pads 11 of the chip 10 and the leads 21 of the leadframe 20. The bumps 13 are composed of gold, copper, lead, fin or silver. The bumps 13 further include several conductive adhesives. The conductive adhesives are composed of lead, tin, copper or silver.

The enhancing layer 14 preferably covers the leads 21 and the bumps 13. Or, the enhancing layer 13 covers only the conductive adhesives of the bumps 13. The enhancing layer 14 is made of metal and preferably a continuous metal layer. The enhancing layer 14 connects the bumps 13 and the leads 21. Moreover, the enhancing layer 14 includes copper preferably. Or, the melting point of the enhancing layer 14 is greater than the melting points of lead and tin. The enhancing layer 14 is formed by electroplating. The encansulant material 30 covers the bumps 13 and a portion of the leadframe 20. Furthermore, before the enhancing layer 14 is formed, the leadframe 20 further includes a thermal resistant tape 23 disposed on a back surface of the leadframe 20. As a result, the encapsulant material 30 is filled more easily and prevented from overflowing. The thermal resistant tape 23 is removed after the encapsulant material 30 is formed. Therefore, the enhancing layer 14 is not formed on the back surface of the leadframe 20. The back surface is the area to adhere the thermal resistant tape 23.

In the above semiconductor package, after the enhancing layer 14 is formed and before the encapsulant material 30 is formed, a thermal resistant tape 23 is adhered to the back surface of the leadframe 20 for filling the encapsulant material 30 more easily and preventing the encapsulant material 30 from overflowing. After the encapsulant material 30 is formed, the thermal resistant tape 23 is removed. As a result, the enhancing layer 14 is also formed on the back surface of the leadframe 20 for preventing the back surface of the leadframe 20 from oxidizing. The chip 10 is protected as well. Please refer to FIGS. 3E˜3F, the enhancing layer 14 is also formed on the back surface of the leadframe 20.

Please referring to FIG. 3B, another semiconductor package with an enhancing layer according to a preferred embodiment of the invention is illustrated in FIG. 3B. A back surface of the chip 10 in FIG. 3B is exposed outside the encapsulant material 30. As a result, FCQFN packages with smaller volume and good heat dissipating ability are more suitable for signal transmission with higher frequency.

Please referring to FIG. 3C, another semiconductor package with an enhancing layer according to a preferred embodiment of the invention is illustrated in FIG. 3C. The semiconductor package includes a leadframe 20, a chip 10, several bumps 13, at least a heat-dissipating bump 15, an enhancing layer 14 and an encapsulant material 30. The leadframe 20 includes several leads 21 and at least a heatsink pad 22. Several bonding pads 11 are disposed on a surface of the chip 10. At least a bonding pad 11 is disposed in a center area of the chip 10. The bumps 13 connect the bonding pads 11 of the chip 10 and the leads 21 of the leadframe 20. The heat-dissipating bump 15 is disposed on the heatsink pad 22. The bumps 13 are composed of gold, copper, lead, tin or silver. The bumps 13 further include several conductive adhesives. The conductive adhesives are composed of lead, tin, copper or silver.

The enhancing layer 14 preferably covers the leads 21 and the bumps 13. Or, the enhancing layer 13 covers only the conductive adhesives of the bumps 13. The enhancing layer 13 is made of metal and preferably a continuous metal layer. The enhancing layer 14 preferably includes copper. Or, the melting point of the enhancing layer 14 is greater than the melting points of lead and tin. Moreover, the enhancing layer 13 is formed by electroplating. The encapsulant material 30 covers the bumps 13 and a portion of the leadframe 20. Preferably, before the enhancing layer 14 is formed, the lead frame further includes a thermal resistant tape 23 disposed on a back surface of the leadframe 20 to prevent the encapsulant material 30 from overflowing. After the encapsulant material 30 is formed, the thermal resistant tape 23 is removed. As a result, the enhancing layer 14 is not formed on the back surface of the leadframe 20. The back surface is the area to adhere the thermal resistant tape 23.

Please referring to FIG. 3D, another semiconductor package with an enhancing layer according to a preferred embodiment of the invention is illustrated in FIG. 3D. A back surface of the chip 10 in FIG. 3D is exposed outside the encapsulant material 30. Therefore, FCQFN packages having less volume and good heat dissipating ability are more suitable for signal transmission with higher frequency.

Please referring to FIG. 3E, another semiconductor package with an enhancing layer according to a preferred embodiment of the invention is illustrated in FIG. 3E. The package includes a leadframe 20, a chip 10, several bumps 13, at least a heat dissipating bump 15, an enhancing layer 14 and an encapsulant material 30. The leadframe 20 includes several leads 21 and at least a heatsink pad 22. Several bonding pads 11 are formed on a surface of the chip 10. At least a bonding pad 11 is formed in a center area of the chip 10. The bumps 13 connect the bonding pads 11 of the chip 10 and the leads 21 of the leadframe 20. The heat dissipating bump 15 is disposed on the heatsink pad 22. The heat dissipating bump 15 is preferably grounded. Furthermore, the heat dissipating bump 15 is bonded to the heatsink pad 22, so that the heatsink pad 22 becomes a ground plane for enhancing the electrical performance of the chip 10. The bumps 13 are composed of gold, copper, lead, tin or silver. The bumps 13 further include several conductive adhesives. The conductive adhesives are composed of lead, tin, copper or silver. However, as long as the conductive adhesives are electrical conductive, the type and the composition of the conductive adhesives are not limited thereto.

The enhancing layer 14 preferably covers the leads 21 and the bumps 13. Or, the enhancing layer 14 covers only the conductive adhesives of the bumps 13. The enhancing layer 14 is made of metal and preferably a continuous metal layer. The enhancing layer 14 preferably includes copper. Or, the melting point of the enhancing layer 14 is greater than the melting points of lead and tin. The enhancing layer 14 is formed by electroplating. The encapsulant material 30 covers the bumps 13 and a portion of the leadframe 20. After the enhancing layer 14 is formed and before the encapsulant 30 is formed, the leadframe 20 further includes a thermal resistant tape 23 disposed on a back surface of the leadframe 20 to prevent the encapsulant material 30 from overflowing. After the encapsulant material 30 is formed, the thermal resistant tape 23 is removed. As a result, the enhancing layer 13 is also formed on the back surface of the leadframe 20. The back surface is the area to adhere the thermal resistant tape 23. The back surface of the leadframe 20 is prevented from oxidizing, and the chip 10 is protected.

Please referring to FIG. 3F, another semiconductor package with an enhancing layer according to a preferred embodiment of the invention is illustrated in FIG. 3F. A back surface of the chip 10 in FIG. 3F is exposed outside the encapsulant material 30. Therefore, FCQFN packages having smaller volume and good heat dissipating ability are more suitable for signal transmission with higher frequency. Moreover, the enhancing layer 14 is also formed on the back surface of the leadframe 20 to prevent the back surface of the leadframe 20 from oxidizing, so that the chip 10 is protected as well.

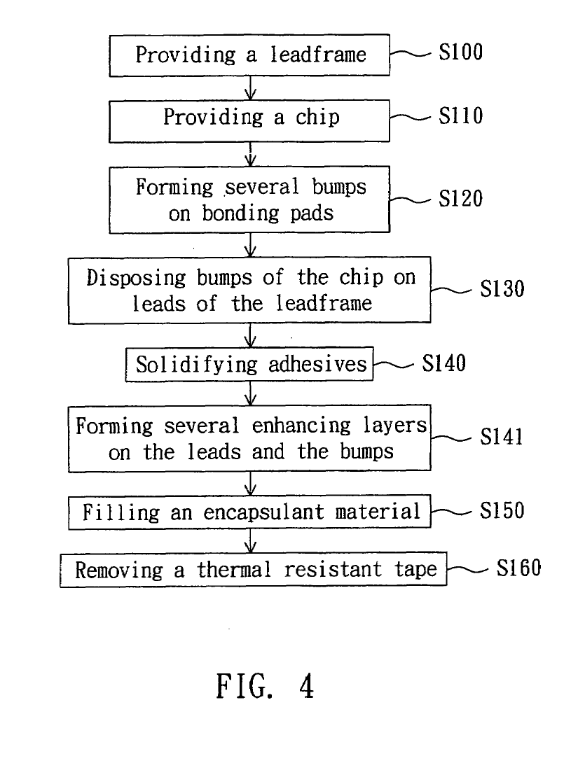

Please referring to FIG. 4, another method for manufacturing a semiconductor package with an enhancing package according to a preferred embodiment of the invention is illustrated in FIG. 4. First, in a step S100, a leadframe 20 including several leads 21 is provided. The leadframe 20 further includes a thermal resistant tape 23 disposed on a back surface of the leadframe 20 to prevent the encapsulant material 30 from overflowing.

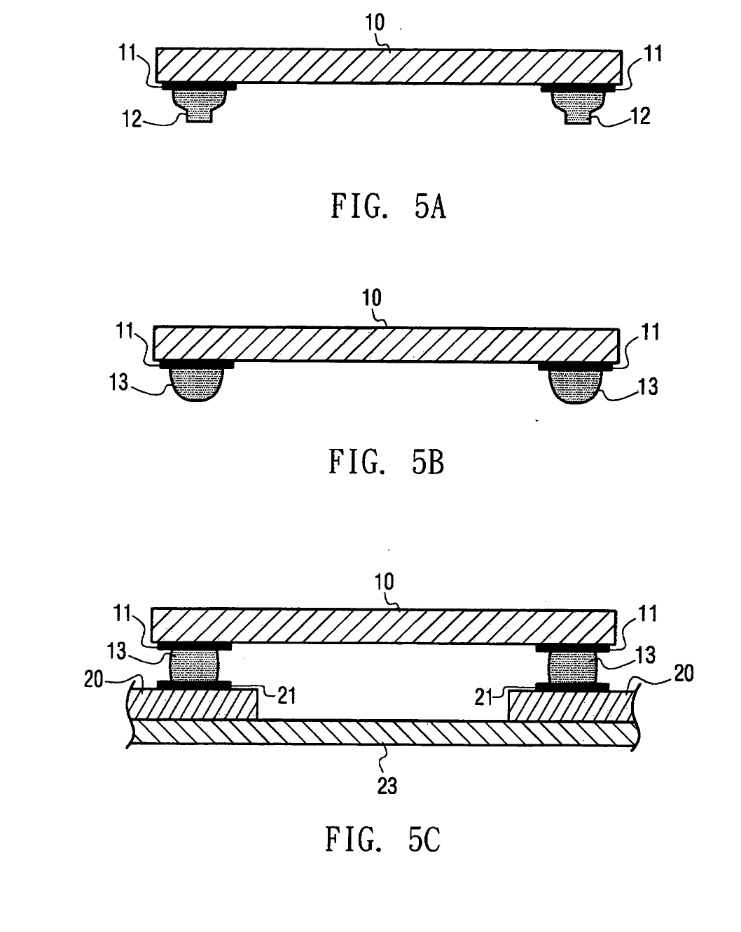

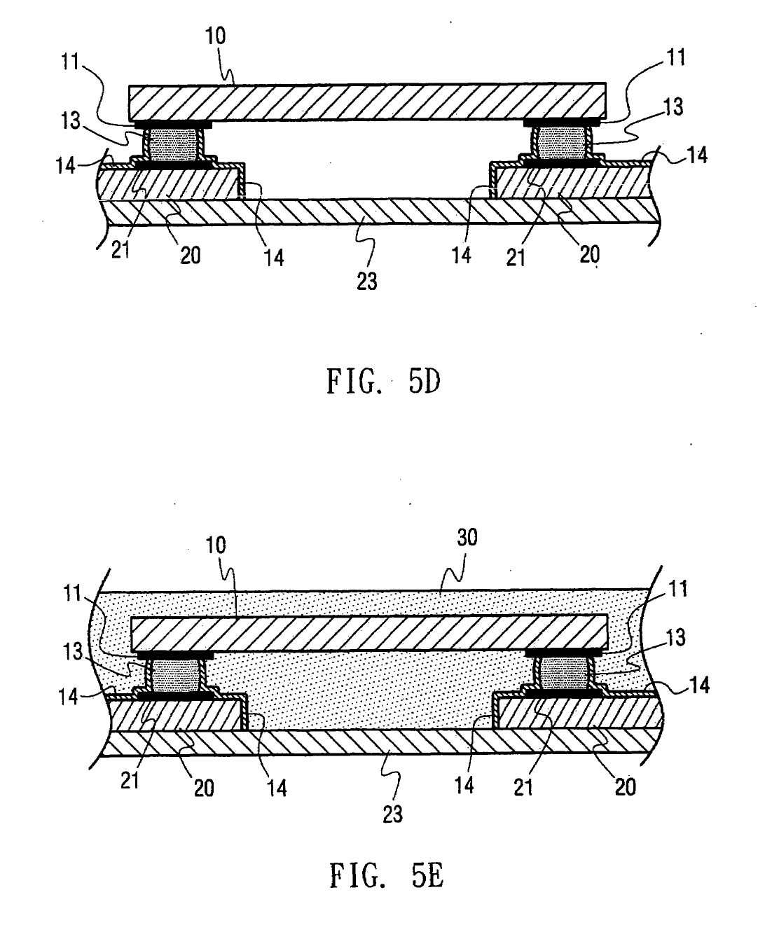

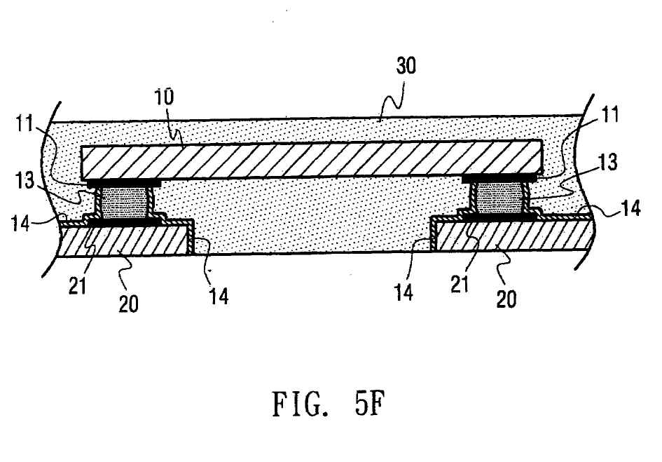

Please referring to FIG. 5A, in a step S110, a chip 10 is provided. Several bonding pads 11 are disposed on a surface of the chip 10. Then, in a step S120, several bumps 12 are formed the bonding pads 11. To achieve the goal of better heat dissipating ability, the leadframe 20 further includes at least a heatsink pad 22. Also, at least a bonding pad 11 and at least a heat dissipating bump 15 are disposed in a center area of the chip 10. The bumps 12 connect the bonding pads 11 of the chip 10 and the leads 21 of the leadframe 20. The heat dissipating bump 15 is disposed on the heatsink pad 22. The bumps 12 are composed of gold, copper, lead, tin or silver. Please referring to FIG. 5B, the bumps 13 further includes several adhesives. The conductive adhesives are composed of lead, tin, copper or silver. However, as long as the adhesive are electrical conductive, the type and the composition of the adhesives are not limited thereto.

Please referring to FIG. 5C, in a step S130, the bumps 13 of the chip 10 are disposed on the leads 21 of the leadframe 20. Afterwards, in a step S140, the adhesives are solidified. The solidifying temperature varies according to the composition of the conductive adhesives. Usually the solidifying temperature is lower than the reflowing temperature 210° C.

Please referring to FIG. 5D, several enhancing layers 14 are formed preferably on the leads 21 and the bumps 13 in a step S141. Or, the enhancing layers 14 cover only the conductive adhesives of the bumps 13. The enhancing layers 14 are made of metal and preferably continuous metal layers. The enhancing layers preferably made of copper. Or, the melting point of the enhancing layers 14 is greater than the melting points of lead and tin. The enhancing layers 14 are formed by electroplating.

Please referring to FIG. 5E, in a step S150, an encapsulant material 30 is filled to cover a portion of the chip 10, the bumps 13 and a portion of the leadframe 20.

Please referring to FIG. 5F, in a step S160, the thermal resistant tape 23 is removed after the encapsulant material 30 is formed. As a result, the enhancing layers 14 are not formed on the back surface of the leadframe 20.

However, in the above method for manufacturing a semiconductor package with an enhancing layer, a thermal resistant tape 23 can be formed on the back surface of the leadframe 20 after the enhancing layers 14 are formed and before the encapsulant material 30 is formed. This step is for preventing the encapsulant material from overflowing. As a result, the enhancing layer 14 is also formed on the back surface of the leadframe 20. The back surface of the leadframe 20 is prevented from oxidizing, so that the chip 10 is protected.

As stated above, the semiconductor package with an enhancing layer according to the invention alleviates the conventional problems including eutectic solder bumps collapsing after reflowing, and bumps collapsing due to large difference of thermal expansion coefficient between the chip and the frame resulted from high reflowing temperature of lead-free and high-lead bumps. Chips are protected from moisture and heat. Also, chips are electrically connected to an outer circuit effectively to achieve the goal of chip packaging.

Furthermore, in the method for manufacturing a semiconductor package of the invention, the bumps and the leads are bonded together without a high temperature reflowing process. The semiconductor packages are prevented from problems, such as residual stress, caused by high temperature process. As a result, the yield rate of the manufacturing process is increased.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A semiconductor package with an enhancing layer, the package comprising:
a leadframe comprising a plurality of leads;
a chip, having a plurality of bonding pads disposed on a surface of the chip;
a plurality of bumps connecting the bonding pads of the chip and the leads of the leadframe; and
an enhancing layer covering the leads and the bumps.

2. The package according to claim 1, wherein the material of the bumps is selected a group comprising of gold, copper, lead, tin and silver.

3. The package according to claim 1, wherein the bumps further comprise a plurality of conductive adhesives.

4. The package according to claim 3, wherein the enhancing layer covers the conductive adhesives of the bumps.

5. The package according to claim 3, wherein the material of the conductive adhesives is selected from a group comprising of lead, tin, copper or silver.

6. The package according to claim 1, wherein the enhancing layer is a metal layer.

7. The package according to claim 1, wherein the enhancing layer comprises copper.

8. The package according to claim 1, wherein the melting point of the enhancing layer is greater the melting point of the material of the bumps.

9. The package according to claim 1, wherein the enhancing layer further covers a portion of the bonding pads.

10. The package according to claim 1, wherein the enhancing layer is a continuous layer.

11. The package according to claim 1, wherein the enhancing layer is an electroplating layer.

12. The package according to claim 1 further comprising an encapsulant material covering the bumps, the enhancing layer and a portion of the leadframe.

13. The package according to claim 12, wherein a back surface of the chip is exposed outside the encapsulant material.

14. The package according to claim 1, wherein the leadframe further comprises at least a heatsink pad, and the chip further comprises at least a heat dissipating bump disposed in a center area of the chip, the heat dissipating bump disposed on the heatsink pad.

15. The package according to claim 14 further comprising an encapsulant material covering the heat dissipating bump, the enhancing layer, a portion of the chip and a portion of the leadframe.

16. The package according to claim 1, wherein the heat dissipating bump is a ground bump or a power bump.

17. The package according to claim 16, wherein a back surface of the chip is exposed outside the encapsulant material.
